(19) United States
(12) Patent Application Publication
(10) Pub. No.: US 2022/0093583 A1
(43) Pub. Date: Mar. 24, 2022

(54) EPITAXIAL STRUCTURE OF GA-FACE GROUP III NITRIDE, ACTIVE DEVICE, AND GATE PROTECTION DEVICE THEREOF

(71) Applicant: CHIH-SHU HUANG, TAIPEI CITY (TW)

(72) Inventor: CHIH-SHU HUANG, TAIPEI CITY (TW)

(21) Appl. No.: 17/457,832

(22) Filed: Dec. 6, 2021

Related U.S. Application Data
(63) Continuation-in-part of application No. 17/017,119, filed on Sep. 10, 2020, now Pat. No. 11,195,943.

(30) Foreign Application Priority Data
Sep. 12, 2019 (TW) 108132995

(51) Int. Cl. H01L 27/02; H01L 29/20; H01L 29/205; H01L 29/778

(52) U.S. Cl. CPC H01L 27/0274; H01L 29/7786; H01L 29/205; H01L 29/2003

(57) ABSTRACT

The present application relates to an epitaxial structure of Ga-face group III nitride and its gate protection device. The epitaxial structure of Ga-face AlGaN/GaN comprises a silicon substrate, a buffer layer (C-doped) on the silicon substrate, an i-GaN (C-doped) layer on the buffer layer (C-doped), an i-Al_{y}GaN buffer layer on the i-GaN (C-doped) layer, an i-GaN channel layer on the i-Al_{y}GaN buffer layer, and an i-AlₓGaN layer on the i-GaN channel layer, where x=0.1˜0.3 and y=0.05˜0.75. By connecting a depletion-mode (D-mode) AlGaN/GaN high electron mobility transistor (HEMT) to the gate of a p-GaN gate enhancement-mode (E-mode) AlGaN/GaN HEMT in device design, the gate of the p-GaN gate E-mode AlGaN/GaN HEMT can be protected under any gate voltage.

### FIELD OF THE INVENTION

The present application relates generally to an epitaxial structure, and particularly to a novel epitaxial structure of Ga-face group III nitride series capable of blocking the electrons of buffer traps from entering the channel layer, and to the active device and the gate protection device formed by using the epitaxial structure.

### BACKGROUND OF THE INVENTION

According to the prior art, the most common structures to achieve an enhancement-mode AlGaN/GaN high electron mobility transistor (E-mode AlGaN/GaN HEMT) include: 1. Ga-face p-GaN gate E-mode HEMT structure, and 2. N-face AlₓGaN gate E-mode HEMT structure. Nonetheless, as implied by their names, only the gate region will be p-GaN or AlₓGaN.

The most common fabrication method is to use an epitaxial structure and etch p-GaN outside the gate region using dry etching while maintaining the completeness of the thickness of the underlying epitaxial layer. Because if the underlying epitaxial layer is etched too much, two-dimensional electron gas (2DEG) will not be formed at the interface AlGaN/GaN of a Ga-face p-GaN gate E-mode HEMT structure. Thereby, the using dry etching is challenging because the etching depth is hard to control and nonuniformity in thickness still occurs in every epitaxial layer of an epitaxial wafer.

Accordingly, to improve the above drawbacks, the present application provides a novel epitaxial structure of Ga-face group III nitride, an active device, and a gate protection device formed by using the epitaxial structure.

### SUMMARY

An objective of the present application is to provide a novel epitaxial structure of Ga-face group III nitride, an active device, and a gate protection device formed by using the epitaxial structure for enabling the gate of a p-GaN gate E-mode AlGaN/GaN HEMT to be protected under any gate voltage. In addition, multiple types of high-voltage and high-speed active devices can be formed on the substrate of the epitaxial structure of Ga-face group III nitride at the same time.

To achieve the above objective, the present application provides an epitaxial structure of AlGaN/GaN HEMT, which includes a gate protection device of D-mode AlGaN/GaN HEMT. The gate protection device is connected to: 1. the gate of a p-GaN gate E-mode AlGaN/GaN HEMT formed by selective epitaxial growth; or 2. the gate of a p-GaN gate E-mode AlGaN/GaN HEMT formed by dry etching. The epitaxial structure of Ga-face AlGaN/GaN as described above comprises a silicon substrate, a buffer layer (C-doped) on the silicon substrate, an i-GaN (C-doped) layer on the buffer layer (C-doped), an i-Al_{y}GaN buffer layer on the i-GaN (C-doped) layer, an i-GaN channel layer on the i-Al_{y}GaN buffer layer, and an i-AlₓGaN layer on the i-GaN channel layer, where x<0.23 and y=0.05^{˜}0.2.

### BRIEF DESCRIPTION OF THE DRAWINGS

FIG. 1 shows distributions of E_{PS} and E_{PZ} in Ga-face and N-face AlGaN/GaN and GaN/InGaN systems in different stains according to the present application;

FIG. 2 shows a schematic diagram of Ga-face and N-face GaN grown on a substrate;

FIG. 3 shows a schematic diagram of the different locations of 2DEG generated at the junctions between AlGaN and GaN due to different polarization according to the present application;

FIG. 4A shows a band diagram of a p-GaN layer grown on the epitaxial structure of AlGaN/GaN HEMT according to the present application;

FIG. 4B to FIG. 4C show the operations of the p-GaN gate E-mode AlGaN/GaN HEMT at a fixed Vd and varying gate voltages Vg according to the present application;

FIG. 4D shows a cross-section and the equivalent circuits of the gate to the GaN layer according to the present application.

FIG. 4E shows forward voltage/current and reversed voltage/current according to the present application.

FIG. 4F show the equivalent circuits of the source of a D-mode AlGaN/GaN HEMT connected to the gate of a p-GaN gate E-mode AlGaN/GaN HEMT.

FIG. 4G shows the voltage and current operating curves of the devices shown in the equivalent circuits in FIG. 4F;

FIG. 5A shows circuit diagrams of a PWM voltage down step circuit IC integrated with the conventional power management IC according to the present application prior art;

FIG. 5B shows circuit diagrams of the external voltage dividing circuit with the power management IC according to the present application;

FIG. 6A and FIG. 6B show circuit diagrams of D-mode AlGaN/GaN HEMT applied with the power management IC according to the present application;

FIG. 7A-1 and FIG. 7A-2 show epitaxial structure diagrams of D-mode AlGaN/GaN HEMT according to the present application;

FIG. 7B shows a cross-sectional view after the drain and source metals corresponding to FIG. 7A-1 and FIG. 7A-2 are fabricated;

FIG. 7C-1 shows a cross-sectional view of dry-etching to the high-resistivity i-GaN buffer layer (C-doped) for isolating devices;

FIG. 7C-2 shows a cross-sectional view of adopting multiple-energy destructive ion implantation to the high-resistivity i-GaN buffer layer (C-doped) for isolating devices;

FIG. 7D-1 and FIG. 7D-2 show cross-sectional views of forming the gate metal and the bonding pads or interconnection metals for drain and source corresponding to FIG. 7C-1 and FIG. 7C-2;

FIG. 7E-1 and FIG. 7E-2 show cross-sectional views of forming and patterning a passivation layer for exposing the drain and source bonding pad regions corresponding to FIG. 7D-1 and FIG. 7D-2;

FIG. 7F-1 and FIG. 7F-2 show cross-sectional views of the D-mode AlGaN/GaN HEMT after the gate field-plate metal is fabricated corresponding to FIG. 7E-1 and FIG. 7E-2;

FIG. 7G shows a top view of the SEG p-GaN gate E-mode AlGaN/GaN HEMT using a D-mode AlGaN/GaN HEMT without gate dielectric layer as the gate protection device;

### DETAILED DESCRIPTION

FIG. 1 shows distributions of E_{PS} and E_{PZ} in Ga-face and N-face AlGaN/GaN and GaN/InGaN systems in different stains according to the present application, where E_{PS} is the spontaneous polarization (the polarization of the material) while E_{PZ} is the piezoelectric polarization (the polarization formed by the piezoelectric effect of strain). Thereby, E_{PS} is determined by the epitaxial layers while E_{PZ} is determined by the piezoelectric effect of strain.

In the AlGaN/GaN system, the value of E_{PZ} is negative when AlGaN is under tensile strain and is positive when AlGaN is under compressive strain. Contrarily, in the GaN/InGaN system, the signs for the values of E_{PZ} are opposite. In addition, according to Reference [2], it is known that, firstly, in the AlGaN/GaN system, the polarization is determined by E_{SP}, and secondly, in the GaN/InGaN system, the polarization is determined by E_{PZ}.

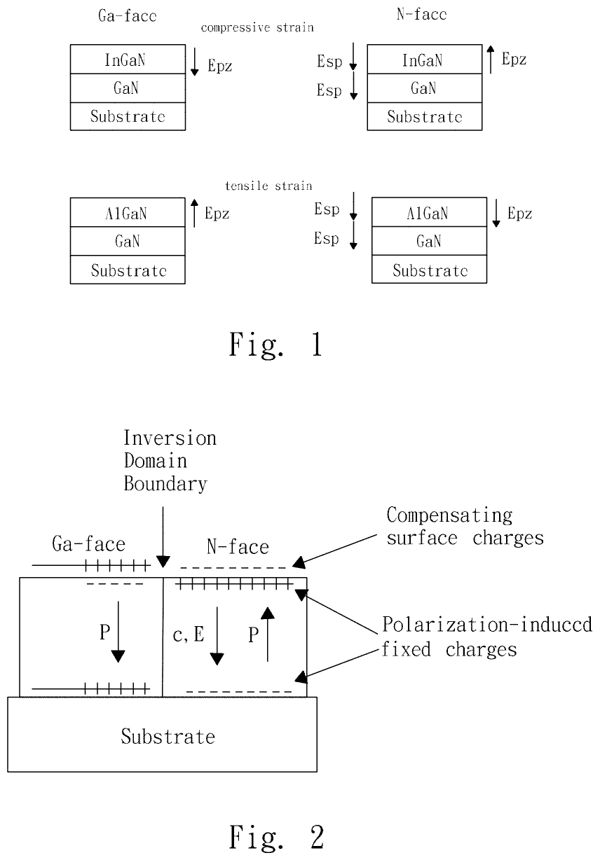

As shown in FIG. 2, P is spontaneous polarization and E is the corresponding electric field. In GaN, the Ga-face (N-face) polarization is determined when the Ga atom (N atom) layer of the Ga—N dual-layer faces the surface of epitaxy. As shown in the figure, a schematic diagram of Ga-face and N-face GaN grown on a substrate is illustrated. If it is Ga-face polarization, the internal electric field is away from the substrate and pointing to the surface. Thereby, the polarization is opposite to the direction of the internal electric field. Consequently, the polarization will cause negative charges to accumulate on the surface of lattice and positive charges to accumulate at the junction with the substrate. On the contrary, if it is N-face polarization, the locations of charge accumulation are swapped and the direction of internal electric field is opposite.

For an AlGaN/GaN HEMT, the most important thing is how the Ga- and N-face polarization influence the device characteristics. FIG. 3 shows a schematic diagram of the different locations of 2DEG generated at the junctions between AlGaN and GaN due to different polarization. In the Ga-face structure, 2DEG exists at the AlGaN/GaN interface while in the N-face structure, 2DEG exists at the GaN/AlGaN interface. The existence of 2DEG indicates accumulation of positive polarization charges at the interface and the 2DEG itself is just the accumulation of free electrons for compensating the polarization charges.

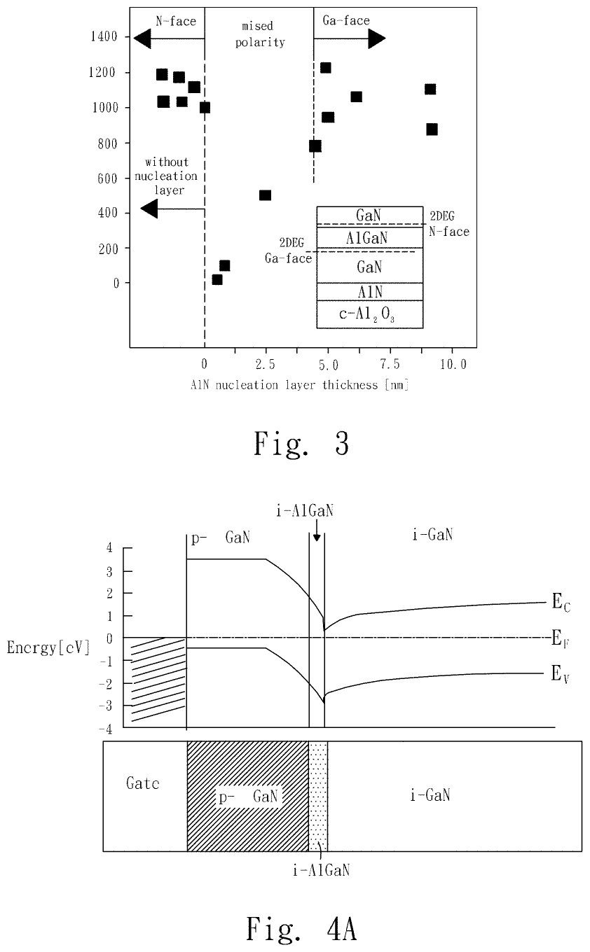

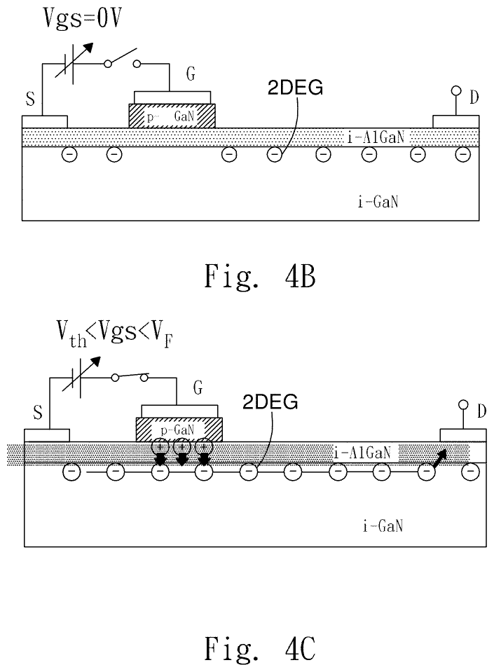

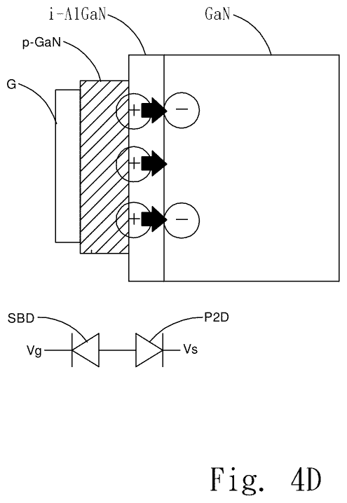

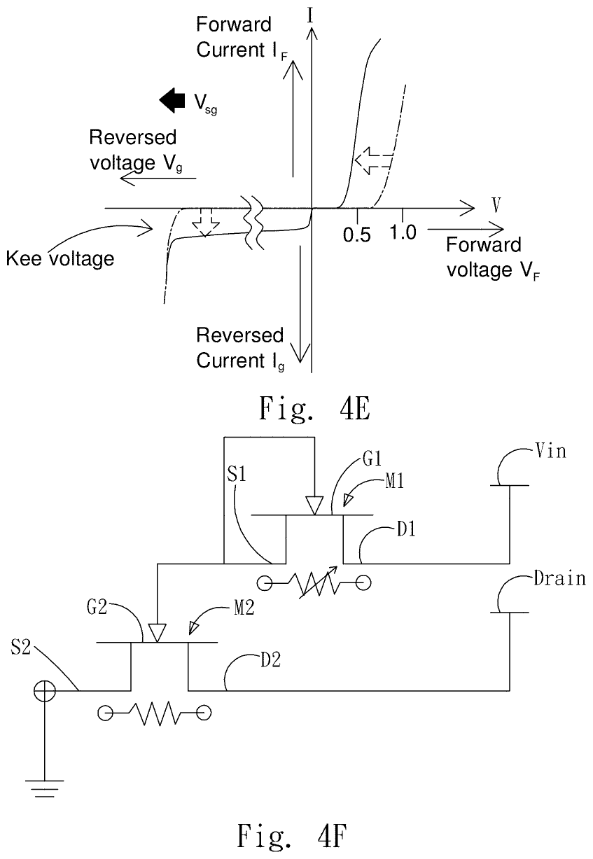

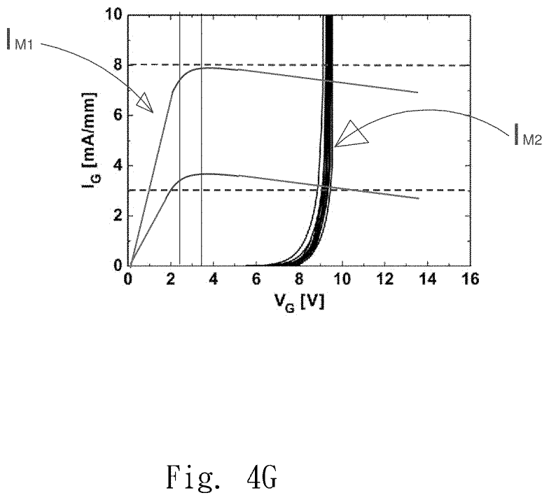

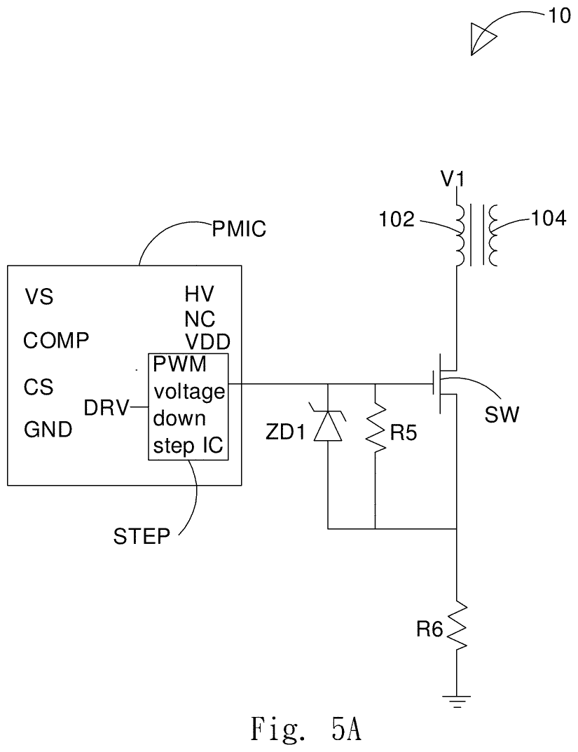

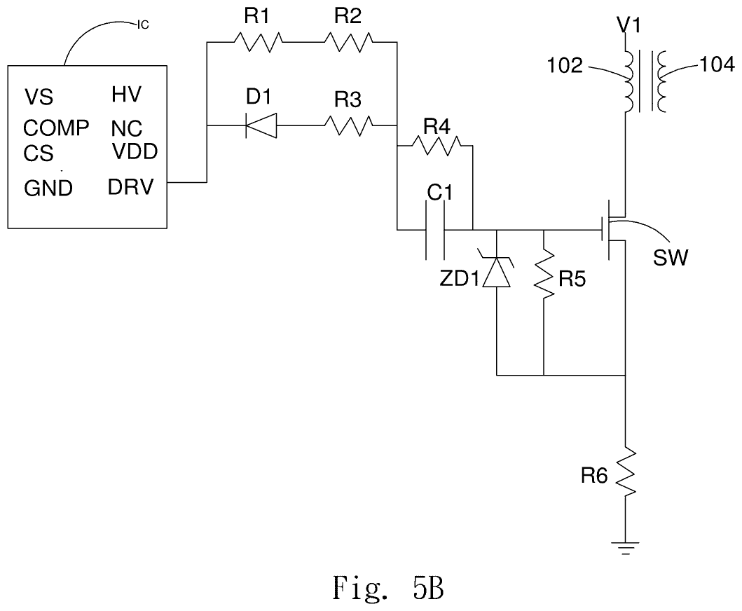

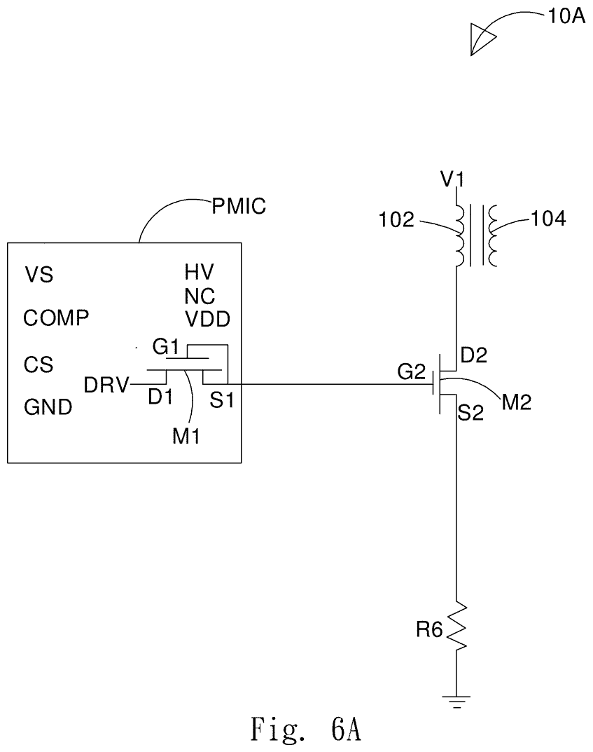

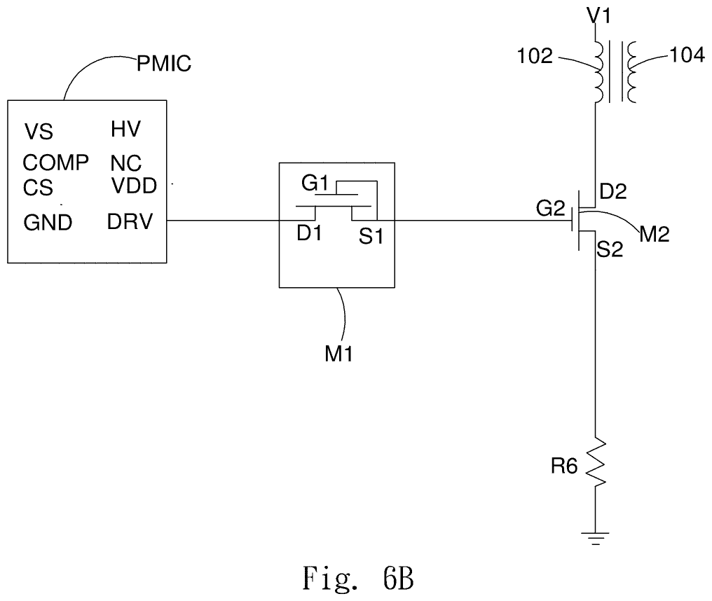

As shown in FIG. 4A to FIG. 4C, the principle of p-GaN gate E-mode AlGaN/GaN HEMT can be viewed from two perspectives. First, by viewing from the polarization electric field, after a p-GaN layer is grown on the epitaxial structure of AlGaN/GaN HEMT, this p-GaN layer will generate a polarization electric field to deplete the 2DEG in the i-GaN channel layer. Secondly, by viewing from the energy band, as shown in FIG. 4A, after a p-GaN layer is grown on the epitaxial structure of AlGaN/GaN HEMT, this p-GaN layer will raise the energy band of the barrier layer i-AlGaN. Thereby, the original potential well at the i-AlGaN/i-GaN junction will be raised above the Fermi energy level, and hence disabling 2DEG from forming.

As shown in FIG. 4B, as the voltage of the p-type gate G is less than or equal to 0, the 2DEG below is completely depleted. Thereby, the current from the drain D cannot pass the channel to reach the source S.

In addition, as shown in the equivalent circuit diagram of FIG. 4D, the gate G of the p-GaN gate E-mode AlGaN/GaN HEMT versus the source S can be viewed as one Schottky diode SBD and one P-type to 2DEG diode P2D connected back-to-back. When a Vgs is given the SBD in a reversely biased state and the P 2D in a forward biased state, VF is defined as Vgs=V(knee voltage) of SBD+Vf of P2D.

As shown in FIG. 4C, as the voltage of the p-type gate G is greater than 0, the potential well at the i-AlGaN/i-GaN junction is suppressed below the Fermi energy level. Thereby, electrons will refill the potential well below and forming 2DEG. When the 2DEG is recovered completely, this positive voltage is defined as the threshold voltage Vth. At this moment, the channel is turned on again and the current from the drain D can pass the channel to reach the source S.

It is very important to note that
1. When a Vgs is given, the SBD is reversely biased, thereby, SBD is in a reversely biased state.
2. When Vgs is greater than Vth and less than VF there will still be holes in the p-type gate G injection into the channel and recombine with the 2DEG electrons which will result with a very small gate current Igs. It is to be note that when Vgs is increased ↑, it will cause that Igs is increased T according to the SBD reversed biased characteristics.
3. Igs is a positive ratio of the p-type gate width (Wg), which means when Wg is increased ↑, Igs is increased T at the mean time.
Thereby, when Vgs is greater than VF, the SBD between the gate G and the source S will be turned on reverse punched through. Massive holes will be injected into the channel layer and making the gate leakage current increase rapidly. Hence, the transistor can no longer operate in the desired condition. Accordingly, the limited value of Vgs is always the shortcoming of a p-GaN gate E-mode AlGaN/GaN HEMT. In general, due to different epitaxy and process conditions, Vgs(max) is around 5-10V. Since the gate trigger voltage of a commercial power control IC is 9-18V, the Schottky gate of the p-GaN gate E-mode AlGaN/GaN HEMT will be punched through directly by the massive gate leakage current Igs generated by the gate trigger voltage and leading to irreversible malfunction of the p-GaN gate E-mode AlGaN/GaN HEMT.

To solve the above problem, as shown in the equivalent circuits in FIG. 4E-1 and FIG. 4E-2, the source of a D-mode AlGaN/GaN HEMT is connected to the gate of a p-GaN gate E-mode AlGaN/GaN HEMT. The source and the gate of the D-mode AlGaN/GaN HEMT M1 are connected electrically using a fabrication method. In other words, the gate G and the source S are shorted (Vgs=0V). Then the D-mode AlGaN/GaN HEMT M1 with Vgs=0V acts as the gate protection device for the p-GaN gate E-mode AlGaN/GaN HEMT M2.

FIG. 4G corresponds to the operating principle and steps of the devices in FIG. 4F. First (Step 1), the p-GaN gate E-mode AlGaN/GaN HEMT M2 must be operated in the condition of Vgs greater than or close to VF, when Igs (the p-GaN gate leakage current) is created, it will turn on the D-mode AlGaN/GaN HEMT M1 at Vgs=0V. Thereby, the Ids of the D-mode AlGaN/GaN HEMT M1 will start to rise (Step 2). When the Ids of the D-mode AlGaN/GaN HEMT M1 has risen to the saturation current Idsat (Step 3), the Igs of the p-GaN gate E-mode AlGaN/GaN HEMT M2 will be fixed to Igs(M2)=Idsat(M1). Thereby, the Vgs of the p-GaN gate E-mode AlGaN/GaN HEMT M2 will be locked to the Vgs when Igs(M2)=Idsat(M1). When the Vin of the D-mode AlGaN/GaN HEMT M1 continues to increase (Step 4), since the Vgs of the p-GaN gate E-mode AlGaN/GaN HEMT M2 is locked, Vin=Vds(M1)+Vgs(M2). Thereby, the p-GaN gate E-mode AlGaN/GaN HEMT M2 will be protected. It is to be note that Idsat(M1) had to be very well controlled by process to fit a desired Igs(M2) in real application, because this Idsat(M1) will cause gate trigger losses for PWM operation. Another important thing is that Idsat(M1) settings also changes when the p-type gate width (Wg) changes.

In the previous example of the inventions, the gate protection device D-Mode HEMT is monolithic integrated with the P-GaN gate E-Mode HEMT. The motivation of the gate protection device D-Mode HEMT connected to the P-GaN gate E-Mode HEMT is to let the P-GaN gate E-Mode HEMT working at Vgs close to VF which is the maximum allowable current, this also where the lowest Rds on can be achieved.

### Prior Arts of Power Management IC:

Using a fly-back AC to DC converting circuit 10 using a P-GaN gate E-Mode HEMT SW as a main switch electrically connected to a primary side inductor 102 of the fly-back AC to DC converting circuit 10 as an example:
The most common way of letting the Vgs working at a safe voltage, normally 5-6.2V, this requires:
1. Using a PWM voltage down step circuit IC STEP integrated with the conventional power management IC PMIC in the same package, as shown in FIG. 5A, creating a gate trigger voltage, wherein a voltage level of the gate trigger voltage=5-6.2V.
2. Using an external voltage dividing circuit (resistors R1, R2, R3, R4, a diode D1, and a capacitor C1), as shown in FIG. 5B, creating a gate trigger voltage=5-6.2V.

Either both ways are not so secure to prevent a gate voltage (DRV) surge in real applications which will destroy P-GaN gate E-Mode HEMT, that's why there is always a Zenor diode (ZD1) needed for providing P-GaN gate E-Mode HEMT gate protection. In this invention, it can divide into 2 types:

1. The gate protection device D-Mode HEMT is integrated with the power management IC in a single packaging lead frame. A driving signal terminal DRV of the power management integrated circuit IC is electrically connected to a drain electrode of the D-Mode HEMT M1, and a gate electrode and a source electrode of the D-Mode HEMT M1 are electrically connected to each other and electrically connected to a gate electrode of the P-GaN gate E-Mode HEMT M2 for gate protection. Since the gate protection device D-Mode HEMT has the capability to operate at Vds close to or greater than 150V, therefore it can absorb any gate voltage (DRV) surge in real applications, thus no Zenor diode (ZD1) is needed for P-GaN gate E-Mode HEMT gate protection. In addition, the external electrical components can be reduced compared to the prior arts, this not only increases the circuit speed but also reduce the PCB layout size.

The P-GaN gate E-Mode HEMT M2 further includes a drain electrode connected to a primary side inductor of a voltage transformer, and a source electrode connected to a resistance R6 for current sensing of the power management integrated circuit IC. 2. The gate protection device D-Mode HEMT is individual packaged in a lead frame. This a similar concept as the first type but in a more flexible way. As mention above, it is to be note that Idsat(M1) had to be very well controlled by process to fit our desired Igs(M2) in real application, because this Idsat(M1) will cause gate trigger losses during PWM operation. Another important thing is that Idsat(M1) settings also changes when the p-type gate width (Wg) changes.

Since the gate protection device D-Mode HEMT becomes individually processed, the design rule becomes more flexible compared to our previous monolithic integrated invention.
There are 3 parameters that can control the D-Mode HEMT gate protection device Id(sat) current more efficiently, which are the percentage composition of Al contained in the AlGaN top barrier layer, the gate width (Wg) of the device and no gate oxide needed.
1. The percentage composition of Al has to be lower than 23%.
2. The Gate Width has to be smaller than 5 um.
3. No gate oxide for speeding up reacting time of the D-Mode HEMT gate protection device, that is, the metal of the gate electrode directly contacts the epitaxial structure of the D-Mode HEMT. Embodiment 1: D-mode AlGaN/GaN HEMT without gate dielectric layer as p-GaN gate D-mode AlGaN/GaN HEMT gate protection device, as shown in FIG. 7A-1 and FIG. 7A-2.

As shown in FIG. 7A-1 and FIG. 7A-2, the epitaxial structure of D-mode AlGaN/GaN HEMT M1, comprises a silicon substrate 11, a buffer layer (C-doped) 12 on the silicon substrate 11, an i-GaN (C-doped) layer 13 on the buffer layer (C-doped) 12, an i-AlyGaN buffer layer 14 on the i-GaN (C-doped) layer 13, an i-GaN channel layer 15 on the i-AlyGaN buffer layer 14, and an i-AlₓGaN layer 16 on the i-GaN channel layer 15, where x<0.23 and y=0.05^{˜}0.2. The different locations of 2DEG 152 generated at the junctions between AlGaN and GaN due to different polarization. Further, the source ohmic contact 28 is electrically connected to the gate field-plate metal 62 via the metal 36, that is, the gate electrode G and the source electrode S of the D-mode AlGaN/GaN HEMT M1 are electrically connected to each other.

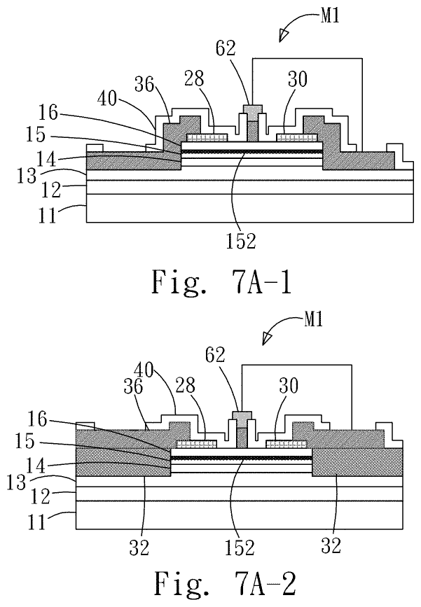

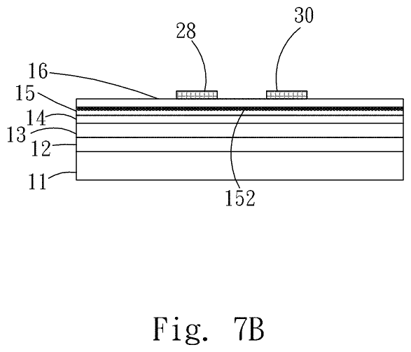

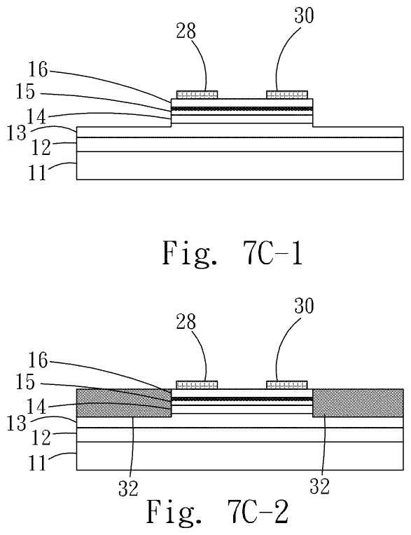

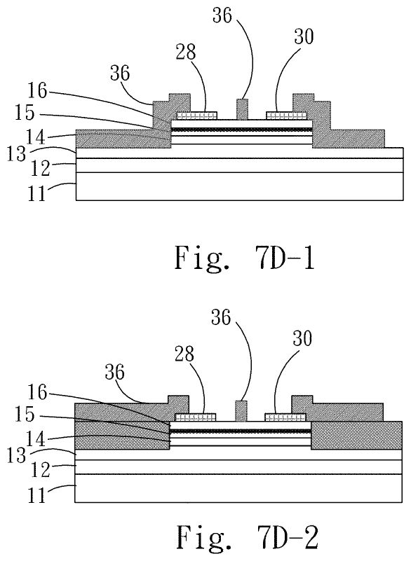

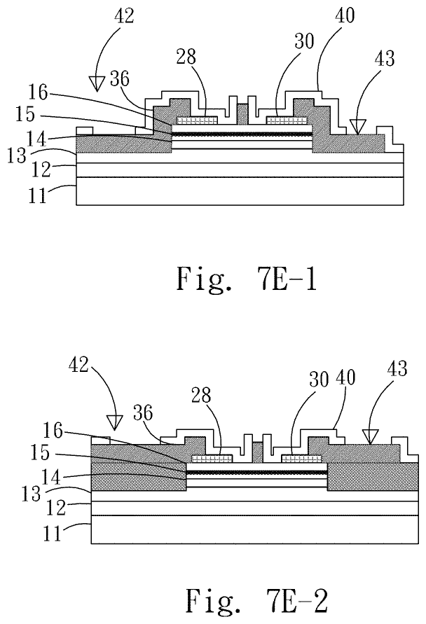

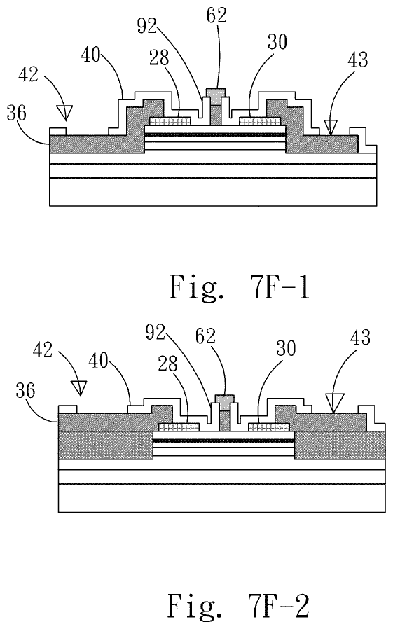

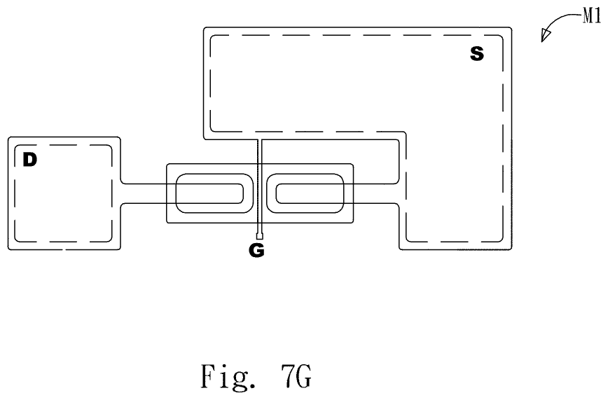

Step S11: Form the drain ohmic contact 30 and the source ohmic contact 28. A metal layer, for example, a general Ti/Al/Ti/Au or Ti/Al/Ni/Au metal layer, is deposited on the epitaxy wafer using metal vapor deposition. Then a metal lift-off method is adopted to pattern the deposited metal layer for forming the drain and source electrodes on the epitaxy wafer. Afterwards, a thermal treatment is performed at 700˜900° C. for 30 seconds to make the drain and source electrodes become ohmic contacts 30, 28, as shown in FIG. 7B.

Step S12: Perform device isolation process. In this step, multiple-energy destructive ion implantation is adopted. In general, heavy atoms such as boron or oxygen atoms are used for isolating devices, as shown in FIG. 7C-2. Alternatively, dry etching to the highly resistive i-GaN buffer layer (C-doped) can be adopted for isolating devices, as shown in FIG. 7C-1.

Step S15: Perform the metal wiring process. In this step, metal deposition is performed. Metal vapor deposition and lift-off methods are used for patterning the Ni/Au metal layer and forming bonding pads for the gate, drain, and source electrodes as well as the interconnection metal 35, as shown in FIG. 7D-1 and FIG. 7D-2. Alternatively, in this step, the gate bonding pad region connected electrically with the gate electrode G can be formed concurrently, as the structures shown in FIG. 7G.

Step S16: Deposit and pattern passivation layer. As shown in FIG. 7E-1 and FIG. 7E-2, a passivation layer 40 is grown by PECVD. The material is selected from the group consisting of SiOₓ, SiOₓN_{y}, or SiNₓ. Finally, the passivation layer 40 is patterned for exposing the bonding pad region. For example, wet etching using BOE is adopted for exposing the drain and source bonding pad regions 42, 43 for subsequent wire bonding.

Step S17: Fabricate the gate field-plate metal. The metal vapor deposition and metal left-off methods are adopted to form the gate field-plate metal 62 for the D-mode HEMT, in the final structures as shown in FIG. 7F-1 and FIG. 7F-2. The gate field-plate metal 62 is adjacent to the gate field-plate dielectric layer 92. The top view of the D-mode AlGaN/GaN HEMT M1 without gate dielectric layer as the gate protection device is shown in FIG. 7G.

1. An D-mode AlGaN/GaN HEMT gate protection device, comprising:
an epitaxial structure of Ga-face AlGaN/GaN; and
a source electrode and a gate electrode, formed on the epitaxial structure of Ga-face AlGaN/GaN and electrically connected to each other, where the D-mode AlGaN/GaN HEMT gate protection device in saturation generates a saturation current corresponding to a Vds of the D-mode AlGaN/GaN HEMT decided by a gate width of the D-mode AlGaN/GaN HEMT smaller than 5 μm;
where the epitaxial structure of Ga-face AlGaN/GaN includes:
a silicon substrate;
a buffer layer (C-doped), located on the silicon substrate;
an i-GaN (C-doped) layer, located on the buffer layer (C-doped);
an i-AlyGaN buffer layer, located on the i-GaN (C-doped) layer;
an i-GaN channel layer, located on the i-AlyGaN buffer layer, the 2DEG formed in the i-GaN channel layer; and
an i-AlₓGaN layer, located on the i-GaN channel layer, where x<0.23 and y=0.05^{˜}0.2.

2. The epitaxial structure of the D-mode AlGaN/GaN HEMT gate protection device of claim 1, wherein the D-mode AlGaN/GaN HEMT gate protection device is integrated with a power management integrated circuit in a single packaging lead frame with a drain electrode of the D-mode AlGaN/GaN HEMT gate protection device electrically connected to a gate trigger output of the power management integrated circuit.

3. The epitaxial structure of the D-mode AlGaN/GaN HEMT gate protection device of claim 2, wherein the D-mode AlGaN/GaN HEMT gate protection device is operated at Vds close to or greater than 150V.

4. The epitaxial structure of the D-mode AlGaN/GaN HEMT gate protection device of claim 1, wherein the D-mode AlGaN/GaN HEMT gate protection device is an individual packaged HEMT in a lead frame with a drain electrode of the D-mode AlGaN/GaN HEMT gate protection device electrically connected to a gate trigger output of a power management integrated circuit.

5. The epitaxial structure of the D-mode AlGaN/GaN HEMT gate protection device of claim 4, wherein the D-mode AlGaN/GaN HEMT gate protection device is operated at Vds close to or greater than 150V.

6. The epitaxial structure of the D-mode AlGaN/GaN HEMT gate protection device of claim 1, wherein the metal of the gate electrode directly contacts the i-AlxGaN layer.

7. A gate protection device, which is an AlGaN/GaN HEMT applied for a power management integrated circuit, the gate protection device comprising,
an epitaxial structure of Ga-face AlGaN/GaN;
a drain electrode, formed on the epitaxial structure of Ga-face AlGaN/GaN, and electrically connected to a driving signal terminal of the power management integrated circuit;
a gate electrode, formed on the epitaxial structure of Ga-face AlGaN/GaN; and
a source electrode, formed on the epitaxial structure of Ga-face AlGaN/GaN, electrically connected to the gate electrode and a gate electrode of a p-GaN gate E-mode AlGaN/GaN HEMT;
wherein the epitaxial structure of Ga-face AlGaN/GaN includes:
a silicon substrate;
a buffer layer (C-doped), located on the silicon substrate;
an i-GaN (C-doped) layer, located on the buffer layer (C-doped);
an i-AlyGaN buffer layer, located on the i-GaN (C-doped) layer;
an i-GaN channel layer, located on the i-AlyGaN buffer layer, the 2DEG formed in the i-GaN channel layer; and
an i-AlxGaN layer, located on the i-GaN channel layer, where x<0.23 and y=0.05^{˜}0.2.

8. The gate protection device of claim 7, wherein the p-GaN gate E-mode AlGaN/GaN HEMT is electrically connected to a primary side inductor of a transformer.

9. The gate protection device of claim 7, wherein the gate protection device is integrated with a power management integrated circuit or individual packaged.

10. A gate protection device, which is an AlGaN/GaN HEMT controlled by a power management integrated circuit, the gate protection device comprising,
an epitaxial structure of Ga-face AlGaN/GaN;
a gate electrode, formed on the epitaxial structure of Ga-face AlGaN/GaN; and
a source electrode, formed on the epitaxial structure of Ga-face AlGaN/GaN, electrically connected to the gate electrode and a gate electrode of a p-GaN gate E-mode AlGaN/GaN HEMT;
wherein the epitaxial structure of Ga-face AlGaN/GaN includes:
a silicon substrate;
a buffer layer (C-doped), located on the silicon substrate;
an i-GaN (C-doped) layer, located on the buffer layer (C-doped);
an i-AlyGaN buffer layer, located on the i-GaN (C-doped) layer;
an i-GaN channel layer, located on the i-AlyGaN buffer layer, the 2DEG formed in the i-GaN channel layer; and
an i-AlxGaN layer, located on the i-GaN channel layer, where x<0.23 and y=0.05^{˜}0.2.

11. The gate protection device of claim 10, wherein the p-GaN gate E-mode AlGaN/GaN HEMT is electrically connected to a primary side inductor of a transformer.
